(19) United States
(12) Patent Application Publication
(10) Pub. No.: US 2026/0327796 A1
(43) Pub. Date: Oct. 22, 2026

(54) APPARATUS FOR FILM DEPOSITION AND PREPARATION METHOD

(71) Applicant: SwaySure Technology Co., Ltd., Shenzhen (CN)

(72) Inventor: Yu Wan, Shenzhen (CN)

(73) Assignee: SwaySure Technology Co., Ltd., Shenzhen (CN)

(21) Appl. No.: 19/641,368

(22) Filed: Apr. 7, 2026

(30) Foreign Application Priority Data
Apr. 21, 2025 (CN) 202510497194.9

(51) Int. Cl. C23C 16/455; C23C 16/44; C23C 16/458; H10P 72/76

(52) U.S. Cl. CPC C23C 16/45519; C23C 16/4408; C23C 16/4412; C23C 16/4584; H10P 72/7618; H10P 72/7621

(57) ABSTRACT

An apparatus for film deposition and a preparation method, by arranging a plurality of rotary disk structures apart from each other in the height direction, and with a plurality of wafer slots distributed circumferentially along the fitting member on each rotary disk structure. When the apparatus for film deposition is working, the rotating structure moves along the height direction and is set in the fitting member of the individual rotary disk structure to drive the corresponding rotary disk structure to rotate. While maintaining the isolation of the gas environment of the wafers in each wafer slot, the gas isolation structure allows the wafers to rotate sequentially through the rotating passage to different isolation spaces to complete the atomic layer film deposition process. This ensures both the spatial isolation effect and the continuous film deposition process.

### CROSS-REFERENCE TO RELATED APPLICATIONS

This application claims priority to Chinese Patent Application No. 202510497194.9, filed on Apr. 21, 2025, in China, the entire disclosure of which is hereby incorporated herein by reference.

### TECHNICAL FIELD

The present disclosure relates to the technical field of semiconductors, and in particular, to an apparatus for film deposition and a preparation method.

### BACKGROUND

With the continuous development of integrated circuit manufacturing processes, atomic layer deposition (ALD) technology has gradually gained widespread application as an important film preparation method, enabling precise control at the atomic level.

Atomic layer deposition, as an advanced film deposition method, involves the cyclic reaction of two reactants on a substrate surface, depositing films layer by layer. ALD boasts excellent film uniformity, precise thickness control, and good step coverage, making it a promising application in semiconductors, microelectronics, and optical devices. In recent years, with the continuous miniaturization of device dimensions, the requirements for atomic layer deposition have increased, especially in terms of deposition speed, via filling capability, and film thickness uniformity, necessitating technological breakthroughs to meet the needs of large-scale production.

### SUMMARY

The problem solved by the present disclosure is to provide an apparatus for film deposition and a preparation method, which can increase the number of wafers that can be processed at one time while ensuring spatial isolation.

To solve the above problem, an apparatus for film deposition is provided in the present disclosure, comprising: a reaction chamber; a plurality of rotary disk structures spaced apart from each other in a height direction, each of the rotary disk structures including a fitting member and a plurality of wafer slots distributed circumferentially along the fitting member; a rotating structure extending in the height direction and movable along the height direction, the rotating structure being disposed in the fitting member of a single rotary disk structure and configured to drive the rotary disk structure to rotate; a plurality of gas isolation structures extending in the height direction, the plurality of gas isolation structures partitioning the reaction chamber into a plurality of isolation spaces, each of the gas isolation structures being provided with a rotating passage through which one rotary disk structure is rotatably passable; wherein a number of isolation spaces is equal to a number of wafer slots in the rotary disk structure; a gas inlet unit, disposed in the reaction chamber; and a gas exhaust unit, disposed in the reaction chamber.

A preparation method for a semiconductor film is further provided in the present disclosure, employing an apparatus for film deposition, wherein each of rotary disk structures comprises four wafer slots, and a reaction chamber is partitioned into four isolation spaces by gas isolation structures, wherein a first isolation space and a fourth isolation space are diagonally arranged, and a second isolation space and a third isolation space are diagonally arranged, the preparation method for the semiconductor film comprising: transferring wafers into the wafer slots of a plurality of layers of the rotary disk structures in the reaction chamber; introducing an inert gas into the reaction chamber to perform purging, after transferring the wafers into the wafer slots; introducing a first reaction gas into the first isolation space while continuously supplying the first reaction gas thereto, and introducing an inert gas into the second isolation space, the third isolation space, and the fourth isolation space; rotating each of the rotary disk structures by 90° under synchronous lifting and lowering coordination of the respective gas isolation structures; introducing a second reaction gas into the fourth isolation space while continuously supplying the second reaction gas thereto, and continuously introducing the inert gas into the second isolation space and the third isolation space, after each of the rotary disk structures is further rotated by 90°; thereafter, under synchronous lifting and lowering coordination of the respective gas isolation structures, rotating each of the rotary disk structures by 90° and maintaining the rotary disk structures for a preset period of time after each rotation; wherein a wafer in each wafer slot sequentially passes through the first isolation space, the third isolation space, the fourth isolation space, and the second isolation space to complete one atomic layer film deposition process, and under synchronous lifting and lowering coordination of the respective gas isolation structures, each wafer repeatedly passes through the first isolation space, the third isolation space, the fourth isolation space, and the second isolation space, achieving multiple cyclic depositions on the wafer to a predetermined thickness, thereby completing the preparation of the film on the wafer.

Compared with the prior art, the technical solutions in the embodiments of the present disclosure have the advantages as follows:

The apparatus for film deposition provided in the embodiment of the present disclosure, by arranging a plurality of rotary disk structures apart from each other in the height direction, and with a plurality of wafer slots distributed circumferentially along the fitting member on each rotary disk structure, can accommodate more wafers for film deposition processing at once, effectively improving the apparatus's production efficiency. Meanwhile, by setting up a gas isolation structure extending in the height direction, the reaction chamber is partitioned into multiple isolation spaces. The number of isolation spaces is equal to the number of wafer slots in the rotary disk structure, making the environment of each wafer slot independent and isolating the gases in the environments of different wafer slots. In addition, a rotating passage is set on the gas isolation structure for the rotary disk structure to rotate through. When the apparatus for film deposition is working, the gas inlet unit in the reaction chamber provides the reaction gas, and the gas exhaust unit removes the waste gas in the chamber. The rotating structure moves along the height direction and is set in the fitting member of the individual rotary disk structure to drive the corresponding rotary disk structure to rotate. While maintaining the isolation of the gas environment of the wafers in each wafer slot, the gas isolation structure allows the wafers to rotate sequentially through the rotating passage to different isolation spaces to complete the atomic layer film deposition process. This ensures both the spatial isolation effect and the continuous film deposition process.

### BRIEF DESCRIPTION OF THE DRAWINGS

FIG. 1 shows a schematic perspective view, shown in a top plan state, of an apparatus for film deposition according to an embodiment of the present disclosure;

FIG. 2 shows a schematic axonometric view of a rotary disk structure, a rotating structure, and a gas isolation structure of an apparatus for film deposition according to an embodiment of the present disclosure;

FIG. 3 shows a schematic front view of a rotary disk structure, a rotating structure, and a gas isolation structure of an apparatus for film deposition according to an embodiment of the present disclosure;

FIG. 4 shows a schematic axonometric view of a rotary disk structure of an apparatus for film deposition according to an embodiment of the present disclosure;

FIG. 5 shows a schematic front view of a rotary disk structure of an apparatus for film deposition according to an embodiment of the present disclosure;

FIG. 6 shows a schematic axonometric view of a rotating structure of an apparatus for film deposition according to an embodiment of the present disclosure;

FIG. 7 shows a schematic front view of a rotating structure of an apparatus for film deposition according to an embodiment of the present disclosure;

FIG. 8 shows a schematic axonometric view of a gas isolation structure of an apparatus for film deposition according to an embodiment of the present disclosure;

FIG. 9 shows a schematic axonometric view of a process gas inlet assembly in a gas inlet unit of an apparatus for film deposition according to an embodiment of the present disclosure;

FIG. 10 shows a schematic structural view of a process gas inlet assembly in a gas inlet unit and a rotary disk structure of an apparatus for film deposition according to an embodiment of the present disclosure;

FIG. 11 shows a flow chart of a preparation method for a semiconductor film according to an embodiment of the present disclosure; and

FIGS. 12-14 are schematic diagrams illustrating deposition of films in respective isolation spaces within a reaction chamber during preparation of a semiconductor film according to an embodiment of the present disclosure.

### DETAILED DESCRIPTION

As can be seen from the background, existing spatially isolated ALD apparatus still has significant limitations. Specifically, the main drawbacks are as follows: First, the single-layer planar rotary disk structure limits the wafer throughput per unit time; second, ensuring effective isolation between process gases is a problem that urgently needs to be solved in spatially isolated ALD apparatus.

To address the aforementioned technical problems, the apparatus for film deposition provided in the embodiment of the present disclosure, by arranging a plurality of rotary disk structures apart from each other in the height direction, and with a plurality of wafer slots distributed circumferentially along the fitting member on each rotary disk structure, can accommodate more wafers for film deposition processing at once, effectively improving the apparatus's production efficiency. Meanwhile, by setting up a gas isolation structure extending in the height direction, the reaction chamber is partitioned into multiple isolation spaces. The number of isolation spaces is equal to the number of wafer slots in the rotary disk structure, making the environment of each wafer slot independent and isolating the gases in the environments of different wafer slots. In addition, a rotating passage is set on the gas isolation structure for the rotary disk structure to rotate through. When the apparatus for film deposition is working, the gas inlet unit in the reaction chamber provides the reaction gas, and the gas exhaust unit removes the waste gas in the chamber. The rotating structure moves along the height direction and is set in the fitting member of the individual rotary disk structure to drive the corresponding rotary disk structure to rotate. While maintaining the isolation of the gas environment of the wafers in each wafer slot, the gas isolation structure allows the wafers to rotate sequentially through the rotating passage to different isolation spaces to complete the atomic layer film deposition process. This ensures both the spatial isolation effect and the continuous film deposition process.

To make the above-mentioned objects, features and advantages of the present disclosure more apparent and understandable, specific embodiments of the present disclosure will be described in detail below with reference to the accompanying drawings.

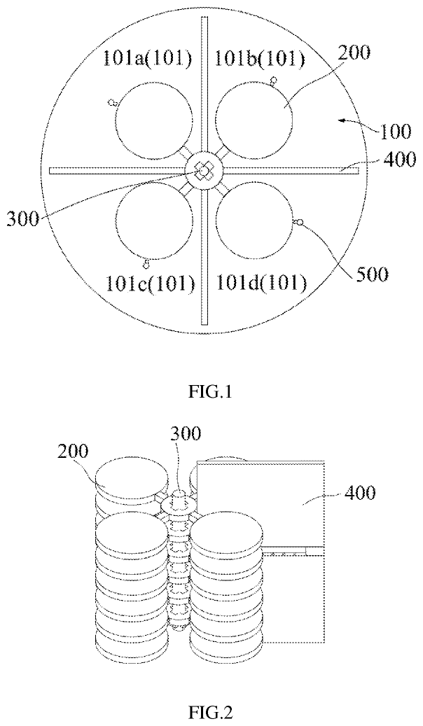

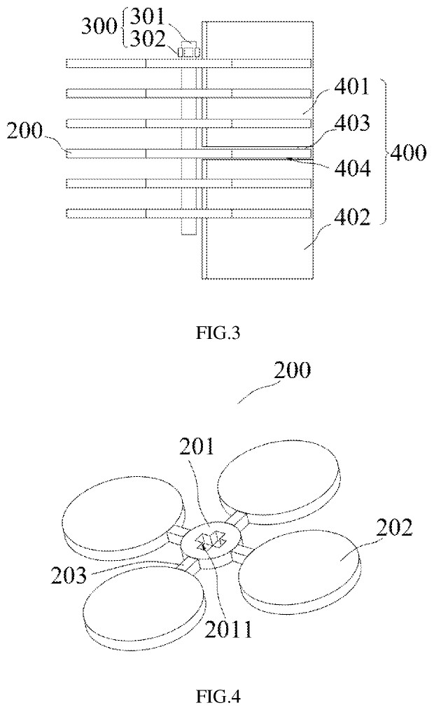

Referring to FIGS. 1 to 10, an apparatus for film deposition is provided in the embodiments of the present disclosure. The apparatus for film deposition includes: a reaction chamber 100; a plurality of rotary disk structures 200 spaced apart from each other in a height direction, each rotary disk structure 200 including a fitting member 201 and a plurality of wafer slots 202 distributed circumferentially along the fitting member 201; a rotating structure 300 extending in the height direction and movable along the height direction, the rotating structure 300 being disposed in the fitting member 201 of a single rotary disk structure 200 and configured to drive the rotary disk structure 200 to rotate; a plurality of gas isolation structures 400 extending in the height direction, the plurality of gas isolation structures partitioning the reaction chamber 100 into multiple isolation spaces 101 (including a first isolation space 101a, a second isolation space 101b, a third isolation space 101c, and a fourth isolation space 101d), each of the gas isolation structures 400 being provided with a rotating passage 404 through which one rotary disk structure 200 is rotatably passable (as shown in FIG. 8), wherein the number of isolation spaces 101 is equal to the number of wafer slots 202 in the rotary disk structure 200; a gas inlet unit (not shown in the figure) disposed in the reaction chamber 100; and a gas exhaust unit (not shown in the figure) disposed in the reaction chamber 100.

The apparatus for film deposition provided in the embodiment of the present disclosure, by arranging a plurality of rotary disk structures 200 apart from each other in the height direction, and with a plurality of wafer slots 202 distributed circumferentially along the fitting member 201 on each rotary disk structure 200, can accommodate more wafers for film deposition processing at once, effectively improving the apparatus's production efficiency. Meanwhile, by setting up a gas isolation structure 400 extending in the height direction, the reaction chamber 100 is partitioned into multiple isolation spaces 101. The number of isolation spaces 101 is equal to the number of wafer slots 202 in the rotary disk structure 200, making the environment of each wafer slot 202 independent and isolating the gases in the environments of different wafer slots 202. In addition, a rotating passage 404 is set on the gas isolation structure 400 for the rotary disk structure 200 to rotate through. When the apparatus for film deposition is working, the gas inlet unit in the reaction chamber 100 provides process gas and isolation gas required by the gas isolation structure 400, and the gas exhaust unit removes the waste gas in the chamber. The rotating structure 300 moves along the height direction and is set in the fitting member 201 of the individual rotary disk structure 200 to drive the corresponding rotary disk structure 200 to rotate. While maintaining the isolation of the gas environment of the wafers in each wafer slot 202, the gas isolation structure 400 allows the wafers to rotate sequentially through the rotating passage 404 to different isolation spaces 101 to complete the atomic layer film deposition process. This ensures both the spatial isolation effect and the continuous film deposition process.

The reaction chamber 100 is used to provide a closed space environment for wafer processing.

In some embodiments, a plurality of rotary disk structures 200 are arranged at intervals in a height direction. Each rotary disk structure 200 includes a fitting member 201 and a plurality of wafer slots 202 distributed circumferentially along the fitting member 201.

By arranging a plurality of rotary disk structures 200 apart from each other in the height direction, and with a plurality of wafer slots 202 distributed circumferentially along the fitting member 201 on each rotary disk structure 200, more wafers can be accommodated at one time for film deposition processing, thus significantly improving the production efficiency of the apparatus for atomic layer deposition.

In some embodiments, there are six rotary disk structures 200, meaning that the reaction chamber 100 can simultaneously accommodate twenty-four wafer slots 202. In other embodiments, the number of rotary disk structures may be four, five, seven, or eight.

In some embodiments, the wafer slots 202 in the rotary disk structure 200 are arranged in a ring array at equal angles with the rotating structure 300 as a center point. This arrangement ensures that each wafer slot 202 maintains an equal distance and angle from the central axis, thereby ensuring that each wafer experiences the exact same process conditions and path during rotation, resulting in good consistency and repeatability in the film deposition process.

In some embodiments, the rotary disk structure 200 includes four wafer slots 202. Compared to existing atomic layer deposition apparatus with only six wafer slots in a single layer, the rotary disk structure 200 increases the spacing between adjacent wafer slots 202, resulting in a sparse distribution of wafers. This effectively avoids gas flow turbulence at the wafer edges, thus significantly improving the uniformity of film deposition. This allows each wafer to undergo atomic layer deposition in a stable gas flow environment, improving the uniformity of film deposition.

As shown in FIGS. 4 and 5, the rotary disk structure 200 includes a support arm 203, configured to support the wafer slot 202. One end of the support arm 203 is connected to a sidewall of the fitting member 201, and the other end of the support arm 203 is connected to the wafer slot 202.

One end of the support arm 203 is connected to the sidewall of the fitting member 201, and the other end is connected to the wafer slot 202, thus supporting the wafer slot 202. This ensures the wafer slot 202 maintains a stable position within the rotary disk structure 200, providing reliable support for the wafer.

It should be noted that the apparatus for film deposition also includes a support structure (not shown in the figure), disposed at a bottom of the fitting member 201, configured to fix the position of the rotary disk structure 200 in the height direction.

In some embodiments, the rotating structure 300 extends in the height direction, is configured to move along the height direction and is disposed in the fitting member 201 of a single rotary disk structure 200, driving the rotary disk structure 200 to rotate.

The rotating structure 300, as a transmission component of the apparatus for film deposition, moves along the height direction and selectively engages with the fitting member 201 of each layer of the rotary disk structure 200, thereby sequentially driving the rotary disk structures 200 at different heights to rotate independently.

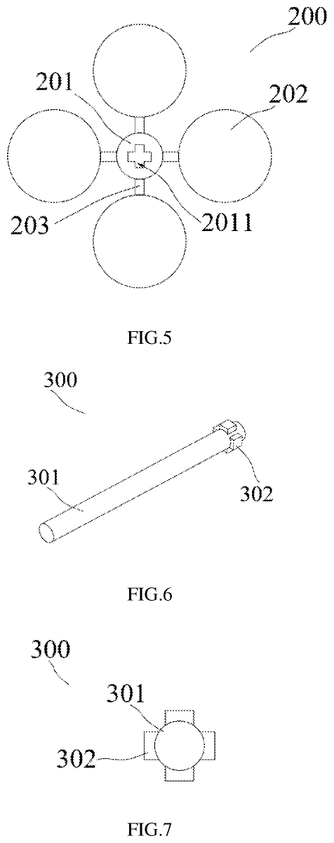

As shown in FIGS. 6 and 7, the rotating structure 300 includes: a rotating shaft 301 extending in the height direction; a plurality of protruding pins 302 radially distributed on a sidewall of the rotating shaft 301 at a same height. The fitting member 201 is disposed at a center of the plurality of wafer slots 202 in the rotary disk structure 200. The fitting member 201 includes a groove 2011 for the protruding pin 302 to be inserted, enabling the rotating shaft 301 to drive the rotary disk structure 200 to rotate.

The rotating shaft 301 of the rotating structure 300 extends in the height direction and has a plurality of protruding pins 302 at a same height; correspondingly, the rotary disk structure 200 has a fitting member 201 at its center, and the fitting member 201 includes a groove 2011 for a protruding pin 302 to be inserted. During apparatus for film deposition operation, the rotating structure 300 moves in the height direction, allowing protruding pins 302 to selectively engage in grooves 2011 of a rotary disk structure 200. This establishes a reliable mechanical connection between the rotating shaft 301 and the rotary disk structure 200, enabling the rotational power of the rotating shaft 301 to be transmitted to the rotary disk structure 200, allowing the wafer to be transferred orderly between different isolation spaces 101 according to a preset process path.

In some embodiments, a plurality of protruding pins 302 are arranged in a ring array at equal angles with the rotating shaft 301 as a center point. Multiple grooves 2011 in the fitting member 201 are interconnected and configured to receive the plurality of protruding pins 302 on the rotating shaft 301.

The multiple grooves 2011 in the fitting member 201 are interconnected, meaning that the central region of the fitting member 201 has a region through which the rotating shaft 301 can pass. The multiple protruding pins 302 on the rotating shaft 301 are arranged in a ring array at equal angles, ensuring that the rotational force is evenly transmitted to the rotary disk structure 200. Therefore, when the protruding pin 302 of the rotating shaft 301 is inserted into the groove 2011 of the fitting member 201, a stable and reliable mechanical transmission structure is formed. This ensures that the rotating shaft 301 can accurately drive the rotary disk structure 200 to complete a predetermined angle of rotation, thus improving the transmission reliability and motion accuracy of the apparatus and helping to ensure the process stability of the film deposition process.

In some embodiments, there are four protruding pins 302, and correspondingly, there are four grooves 2011 in the fitting member 201.

It should be noted that the four grooves in the fitting member 201 form a cross-shaped through hole.

It should also be noted that in some embodiments, the rotating shaft 301 penetrates the top and bottom walls of the reaction chamber 100, and the rotating shaft 301 is also connected to a drive mechanism, such as a drive motor (not shown in the figure). In other embodiments, the rotating shaft 301 may also be disposed within the reaction chamber.

In some embodiments, multiple gas isolation structures 400 extend in the height direction, and the multiple gas isolation structures 400 partition the reaction chamber 100 into multiple isolation spaces 101. Each gas isolation structure 400 is provided with a rotating passage 404 through which one rotary disk structure 200 is rotatably passable. The number of isolation spaces 101 is equal to the number of wafer slots 202 in the rotary disk structure 200.

The gas isolation structure 400 extends in the height direction, dividing the reaction chamber 100 into multiple independent isolation spaces 101. This ensures that the environments of each wafer slot 202 are independent. When the apparatus for film deposition is working, each isolation space 101 has a different gas environment, and adjacent isolation spaces 101 are isolated from each other. This allows the alternating deposition process required for atomic layer deposition to proceed reliably, helping to ensure the quality and uniformity of the film deposition. Simultaneously, by providing a rotating passage 404 on the gas isolation structure 400, while ensuring gas isolation, the wafers in the wafer slots 202 can sequentially undergo surface adsorption and residual purging of different reaction precursor gases, continuously cycling the atomic layer-level film deposition process to the preset thickness.

It should be noted that the reaction chamber 100 is partitioned into four isolation spaces 101 by the gas isolation structure 400, where the first isolation space 101a and the fourth isolation space 101d are arranged diagonally, and the second isolation space 101b and the third isolation space 101c are also arranged diagonally.

In some embodiments, as shown in FIG. 8, the gas isolation structure 400 includes: a first gas curtain plate 401; and a second gas curtain plate 402, disposed at a bottom of the first gas curtain plate 401 and spaced apart from the first gas curtain plate 401 at a fixed distance. The space between the second gas curtain plate 402 and the first gas curtain plate 401 serves as a rotating passage 404.

The gas isolation structure 400, through the first gas curtain plate 401 and the second gas curtain plate 402, forms a stable gas curtain barrier, which helps prevent the mutual diffusion of gases in different isolation spaces. This ensures the independence of the environment in each wafer slot 202, thus preventing cross-contamination between the gas environments in different isolation spaces 101. This allows the atomic layer deposition process to proceed smoothly and helps ensure the quality of the film deposition. Furthermore, using the space between the first gas curtain plate 401 and the second gas curtain plate 402 as the rotating passage 404 allows the rotary disk structure 200 to rotate smoothly through the gas curtain, thereby achieving a continuous film deposition process, meeting the process requirements of atomic layer deposition.

In some embodiments, the gas isolation structure 400 further includes a gas curtain plate fixing member 403, disposed between the bottom of the first gas curtain plate 401 and the top of the second gas curtain plate 402, and located at an outer edge of the first gas curtain plate 401 and the second gas curtain plate 402 away from the rotating structure 300, for maintaining a fixed distance between the first gas curtain plate 401 and the second gas curtain plate 402.

The gas curtain plate fixing member 403 is disposed between the bottom of the first gas curtain plate 401 and the top of the second gas curtain plate 402, thereby fixing the distance between the first gas curtain plate 401 and the second gas curtain plate 402 and providing a rotating passage 404 for the rotation of the rotary disk structure 200; furthermore, because the gas curtain plate fixing member 403 is disposed at the outer edge of the first gas curtain plate 401 and the second gas curtain plate 402 away from the rotating structure 300, interference between the rotary disk structure 200 and the gas curtain plate fixing member 403 is avoided when the rotary disk structure 200 rotates.

In some embodiments, the top of the first gas curtain plate 401 has a first gas inlet (not shown in the figure), and the bottom of the first gas curtain plate 401 includes a plurality of first gas outlets arranged at intervals (not shown in the figure), which is in fluid communication with the first gas inlet. Inert gas is transported to the top of the second gas curtain plate 402 after passing through the first gas inlet and the first gas outlet. The top of the second gas curtain plate 402 includes a plurality of second gas inlets 402a arranged at intervals, corresponding to the first gas outlets, for absorbing gas. The bottom of the second gas curtain plate has a second gas outlet (not shown in the figure).

Inert gas is supplied through the first gas inlet of the first gas curtain plate 401 and uniformly sprayed through the first gas outlets spaced apart at the bottom. The gas is then absorbed by the second gas inlet 402a at the top of the second gas curtain plate 402, thus forming a continuous and stable gas curtain barrier between the first gas curtain plate 401 and the second gas curtain plate 402, ensuring that the environments of each wafer slot 202 are independent. Simultaneously, by providing a rotating passage 404 on the gas isolation structure 400, a continuous, multi-cycle atomic-level film deposition process is achieved to a preset thickness. Therefore, the gas isolation structure 400 maintains the gas isolation effect while ensuring a continuous film deposition process, ultimately resulting in a significant increase in apparatus productivity.

In some embodiments, the gas inlet unit includes: a gas curtain gas inlet assembly (not shown in the figure), in fluid communication with the first gas inlet, for supplying isolation gas to the gas isolation structure 400; and a gas exhaust unit includes: a gas curtain gas exhaust assembly (not shown in the figure), in fluid communication with the second gas outlet corresponding to the second gas inlet 402a, for extracting gas from the gas isolation structure. It should be noted that the second gas outlet is located at the bottom of the second gas curtain plate 402.

The gas curtain gas exhaust assembly, as a crucial component of the gas exhaust unit, forms a communication structure with the bottom of the second gas inlet 402a of each gas isolation structure 400. This allows for continuous extraction of gas from the second gas inlet 402a, ensuring effective gas circulation within the gas isolation structure 400.

In some embodiments, there are four wafer slots 202, and correspondingly, four gas isolation structures 400.

It should also be noted that the gas isolation structure 400 extends through the top and bottom of the reaction chamber 100 in the height direction, and is slidable in the height direction to move upward and downward.

A gas isolation structure 400 extends through the top and bottom of the reaction chamber 100, effectively isolating gases within the height range of the reaction chamber 100. Furthermore, by raising and lowering the gas isolation structure 400 in the height direction, the height of the rotating passage 404 is matched with the position of the rotary disk structure 200, preparing for the rotation of the rotary disk structure 200. This ensures that each layer of the rotary disk structure 200 can rotate sequentially through the rotating passage 404 of its respective gas isolation structure 400, allowing for the processing of a larger number of wafers in a single atomic layer film deposition process, thus improving the throughput of the apparatus for film deposition.

It should be noted that the apparatus for film deposition also includes a sealing structure (not shown in the figure), disposed between the gas isolation structure 400 and the top of the reaction chamber, and between the gas isolation structure 400 and the bottom of the reaction chamber, achieving a seal and preventing gas in the reaction chamber 100 from leaking out through the gaps between the gas isolation structure 400 and the top and bottom of the reaction chamber 100.

The apparatus for film deposition also includes a lifting mechanism (not shown in the figure), located below the reaction chamber 100, and the output end of the lifting mechanism is connected to the bottom of the gas isolation structure 400.

The lifting mechanism, connected to the bottom of the gas isolation structure 400, drives the gas isolation structure 400 to move upward and downward in the height direction, ensuring that the rotating passage 404 of the gas isolation structure 400 aligns sequentially with each layer of the rotary disk structure 200. This achieves coordinated movement between the gas isolation structure 400 and the rotary disk structure 200, allowing the wafer to be transferred while maintaining gas isolation, thus ensuring the continuous execution of the atomic layer deposition process.

The lifting mechanism, as the lifting power source for the movement of the gas isolation structure 400, is directly connected to the gas isolation structure 400. During the process, the movement of the lifting mechanism and the rotation of the rotary disk structure 200 must be precisely coordinated to ensure that the rotating passage 404 of the gas isolation structure 400 is aligned with the position of the rotary disk structure 200 at the correct time.

In some embodiments, the lifting mechanism needs to have precise position control and smooth movement. The lifting mechanism includes a servo motor. The ball screw mechanism driven by the servo motor, in conjunction with the linear guide rail, can achieve stable lifting movement. Moreover, the servo motor can provide accurate position feedback, ensuring that the rotating passage 404 of the gas isolation structure 400 can be precisely aligned with the position of rotary disk structure 200 of each layer. In other embodiments, the lifting mechanism can also use a combination of a cylinder and a guide mechanism. The cylinder provides lifting power, and the guide mechanism helps to achieve smooth movement.

In some embodiments, the gas inlet unit and the gas exhaust unit are disposed within the reaction chamber 100.

The gas inlet unit and the gas exhaust unit, disposed within the reaction chamber 100, enable the directional delivery of process gases and isolation gases and the timely removal of waste gases. This provides a suitable process gas environment for film deposition on the wafer, thereby facilitating the smooth progress of the atomic layer deposition process and improving the uniformity and quality of the film deposition.

In some embodiments, the gas inlet unit further includes multiple process gas inlet assemblies 500, and the gas exhaust unit includes multiple waste gas exhaust assemblies (not shown in the figure). An isolation space 101 contains one process gas inlet assembly 500 and one waste gas exhaust assembly. The waste gas exhaust assembly is located on the side of the wafer slot 202 near the rotating structure 300, while the process gas inlet assembly 500 is located on the side of the wafer slot 202 away from the rotating structure 300.

The waste gas exhaust assembly is located on the side of the wafer slot 202 near the rotating structure 300, while the process gas inlet assembly 500 is located on the side of the wafer slot 202 away from the rotating structure 300. When the apparatus for film deposition is working, the process gas enters the reaction chamber 100 from the side of the wafer slot 202 away from the rotating structure 300 and leaves the reaction chamber 100 from the side of the wafer slot 202 near the rotating structure 300. This allows the process gas to fully contact the wafer surface, thus preventing the gas from being directly extracted after entering the reaction chamber 100 from the process gas inlet assembly 500. This improves the utilization efficiency of the process gas and enables the film deposition process to proceed stably and uniformly.

In some embodiments, multiple process gas inlet assemblies 500 are arranged in a ring array at equal angles with the rotating structure 300 as a center point, and multiple waste gas exhaust assemblies are arranged in a ring array at equal angles with the rotating structure 300 as a center point. The line connecting the center point of the process gas inlet assemblies 500 and the center point of the waste gas exhaust assemblies passes through the center point of the rotating structure 300, ensuring the uniform distribution of process gas on the wafer and making the film deposition more uniform.

In other embodiments, the process gas inlet assembly is located on the side of the wafer slot closer to the rotating structure, and the waste gas exhaust assembly is located on the side of the wafer slot away from the rotating structure.

The process gas inlet assembly is located on the side of the wafer slot closer to the rotating structure, and the waste gas exhaust assembly is located on the side of the wafer slot away from the rotating structure. When the apparatus for film deposition is working, the process gas enters the reaction chamber from the side of the wafer slot near the rotating structure and leaves the reaction chamber from the side of the wafer slot away from the rotating structure. This allows the process gas to fully contact the wafer surface, thus preventing the gas from being directly extracted after entering the reaction chamber from the process gas inlet assembly. This improves the utilization efficiency of the reaction gas and enables the film deposition process to proceed stably and uniformly.

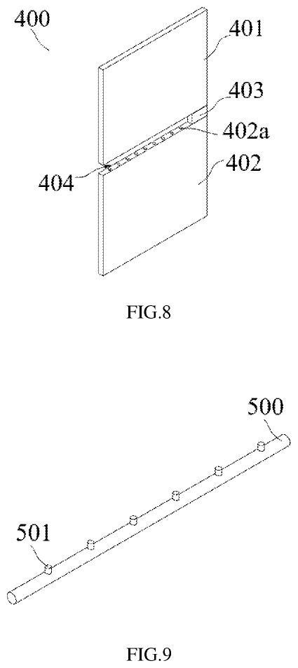

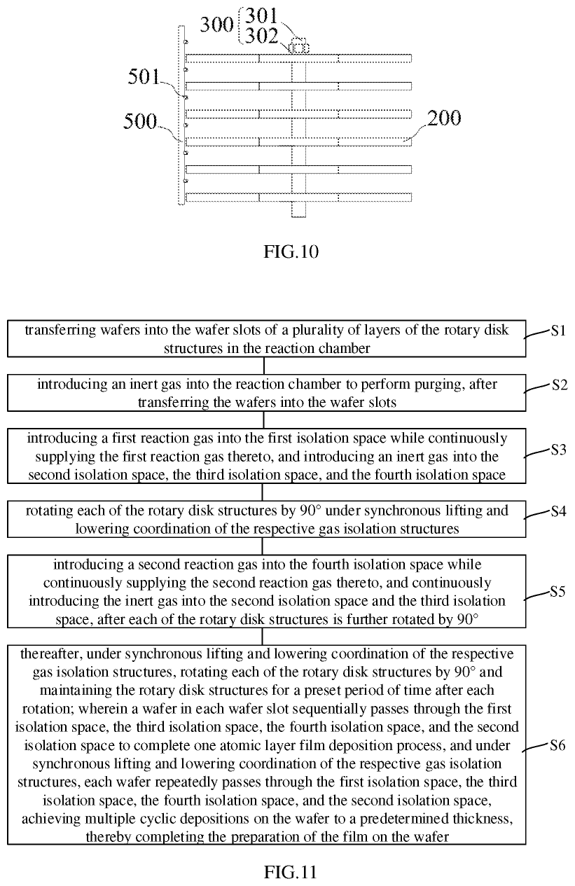

As shown in FIGS. 9 and 10, the process gas inlet assembly 500 extends along the height direction. Each process gas inlet assembly 500 is provided with a jet pipe 501 corresponding one-to-one with a plurality of wafer slots 202 along the height direction, and the jet pipe 501 is disposed above a side of the corresponding wafer slot 202.

Multiple jet pipes 501 on the process gas inlet assembly 500 correspond one-to-one with the wafer slots 202 of different levels in the height direction. The process gas inlet assembly 500 delivers gas to the wafers on the wafer slots 202 through the jet pipes 501, ensuring a stable and uniform gas supply to each wafer slot 202. This improves the controllability of the atomic layer deposition process, thus ensuring the uniformity and quality of film deposition and enabling simultaneous processing of multilayer wafers.

In some embodiments, there are six rotary disk structures, therefore, there are six jet pipes 501 on the process gas inlet assembly 500.

It should be noted that during the operation of the apparatus for film deposition, in adjacent isolation spaces 101, the process gas inlet assembly 500 in one isolation space 101 provides reaction gas, while the process gas inlet assembly 500 in the other isolation space 101 provides purge gas, such as an inert gas.

In some embodiments, there are multiple process gas inlet assemblies 500, which are arranged at equal angles around the rotary disk structure 200 with the rotating structure 300 as a center point. The number of process gas inlet assemblies 500 is equal to the number of isolation spaces.

The arrangement of multiple process gas inlet assemblies 500 at equal angles with the rotating structure 300 as a center point, and the fact that their number is equal to the number of isolation spaces, ensures that each isolation space 101 receives an independent and uniform gas supply. This guarantees sufficient contact between the gas and each wafer, thereby ensuring the consistency of the film deposition process. This improves the uniformity of product quality and allows for stable process levels in batch processing.

In other embodiments, the number of process gas inlet assemblies may be twice the number of isolation spaces, that is, two process gas inlet assemblies 500 are provided in one isolation space.

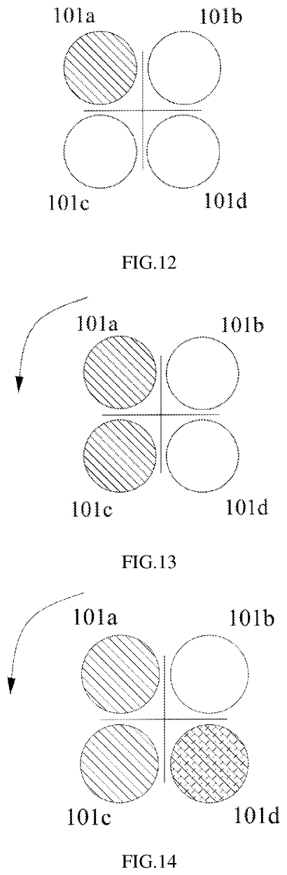

Referring to FIGS. 11 to 14, the embodiment of the present disclosure also provides a preparation method for a semiconductor film, employing the aforementioned apparatus for film deposition. Each of rotary disk structures 200 comprises four wafer slots 202, and a reaction chamber 100 is partitioned into four isolation spaces 101 by gas isolation structures 400, wherein a first isolation space 101a and a fourth isolation space 101d are diagonally arranged, and a second isolation space 101b and a third isolation space 101c are diagonally arranged. The preparation method for the semiconductor film includes: step S1, transferring wafers into the wafer slots 202 of a plurality of layers of the rotary disk structures 200 in the reaction chamber 100; step S2, introducing an inert gas into the reaction chamber 100 to perform purging, after transferring the wafers into the wafer slots 202; step S3, as shown in FIG. 12, introducing a first reaction gas into the first isolation space 101a while continuously supplying the first reaction gas thereto, and introducing an inert gas into the second isolation space 101b, the third isolation space 101c, and the fourth isolation space 101d; step S4, as shown in FIG. 13, rotating each of the rotary disk structures 200 by 90° under synchronous lifting and lowering coordination of the respective gas isolation structures 400; step S5, as shown in FIG. 14, introducing a second reaction gas into the fourth isolation space 101d while continuously supplying the second reaction gas thereto, and continuously introducing the inert gas into the second isolation space 101b and the third isolation space 101c, after each of the rotary disk structures 200 is further rotated by 90°; step S6, thereafter, under synchronous lifting and lowering coordination of the respective gas isolation structures 400, rotating each of the rotary disk structures 200 by 90° and maintaining the rotary disk structures for a preset period of time after each rotation; wherein a wafer in each wafer slot 202 sequentially passes through the first isolation space 101a, the third isolation space 101c, the fourth isolation space 101d, and the second isolation space 101b to complete one atomic layer film deposition process, and under synchronous lifting and lowering coordination of the respective gas isolation structures 400, each wafer repeatedly passes through the first isolation space 101a, the third isolation space 101c, the fourth isolation space 101d, and the second isolation space 101b, achieving multiple cyclic depositions on the wafer to a predetermined thickness, thereby completing the preparation of the film on the wafer.

The preparation method for a semiconductor film provided in the present disclosure, uses a gas isolation structure 400 to partition the reaction chamber 100 into four diagonally arranged isolation spaces 101 (the first isolation space 101a and the fourth isolation space 101d are diagonally arranged, and the second isolation space 101b and the third isolation space 101c are diagonally arranged). When the rotating passage 404 of the gas isolation structure 400 moves to the height of the rotary disk structure 200, the rotary disk structure 200 completes a 90° rotation. The gas isolation structure 400 achieves coordinated operation between the rotary disk rotation and gas isolation, thus laying the structural foundation for subsequent film deposition processes. First, the wafer is transferred to the wafer slot 202 of the multilayer rotary disk structure 200 in the reaction chamber 100. Then, inert gas is introduced into the reaction chamber through the gas inlet unit for purging, thereby removing impurities in the reaction environment and ensuring the purity of the reaction environment. During film deposition, the first reaction gas is continuously introduced into the first isolation space 101a through the process gas inlet assembly 500, while the second isolation space 101b, the third isolation space 101c, and the fourth isolation space 101d are introduced with inert gases through their respective process gas inlet assemblies 500, thus confining the reaction gas within the first isolation space 101a. Subsequently, with the synchronous lifting and lowering coordination of the gas isolation structure 400, each rotary disk structure 200 completes a 90°rotation, allowing the wafer to move along a predetermined trajectory. After each of the rotary disk structures is further rotated by 90°, the second reaction gas is introduced into the fourth isolation space 101d through the process gas inlet assembly 500, while inert gases are continuously introduced into the second isolation space 101b and the third isolation space 101c, thus constructing a complete film deposition cycle system. During the rotation of the rotary disk structure 200, the wafer sequentially passes through the first isolation space 101a, the third isolation space 101c, the fourth isolation space 101d, and the second isolation space 101b, completing a full atomic-layer film deposition process. By controlling the rotary disk structure 200 to cycle through this process multiple times, precise deposition of a film of a preset thickness is achieved. The preparation method for a semiconductor film provided in the present disclosure utilizes the spatial isolation effect of the gas isolation structure 400 and the continuous rotation of the rotary disk structure 200 to ensure that the environment of each wafer slot 202 remains independent, while simultaneously ensuring the continuity of the thin film deposition process.

In some embodiments, the preparation method for a semiconductor film further includes: after the wafer is transferred to the wafer slot 202 of the multilayer rotary disk structure 200 in the reaction chamber 100, the reaction chamber 100 is evacuated.

Vacuuming the reaction chamber 100 is performed after wafer loading and before the start of the film deposition process. Vacuuming is carried out by the gas exhaust unit to remove impurity gases from the reaction chamber 100, thereby establishing a clean vacuum environment. This provides controllable reaction conditions for the subsequent atomic layer film deposition process, effectively preventing impurity gases from interfering with the atomic layer growth process of the film, and enabling the film deposition process to be carried out in a pure and stable environment.

In some embodiments, a first reaction gas is introduced into the first isolation space 101a and continuously ventilated, while inert gases are introduced into the second isolation space 101b, the third isolation space 101c, and the fourth isolation space 101d.

By introducing a first reaction gas into the first isolation space 101a and inert gases into the second isolation spaces 101b, third isolation spaces 101c, and fourth isolation spaces 101d, the first reaction gas is confined to the first isolation space 101a, preventing it from diffusing into the second isolation spaces 101b, third isolation spaces 101c, and fourth isolation spaces 101d. This ensures that the reaction gases do not mix or interfere with each other, allowing the atomic layer deposition process to proceed under controlled conditions. This is beneficial for improving the uniformity and quality of film deposition.

In some embodiments, with the synchronous lifting and lowering of each gas isolation structure 400, each rotary disk structure 200 rotates by 90°.

The synchronous lifting and lowering of the gas isolation structures 400 and the 90° rotation of the rotary disk structures 200 work together to achieve precise transfer of the wafer on the rotary disk structure 200 between the different isolation spaces 101, enabling the entire deposition process to proceed continuously and stably.

Specifically, the process of rotating each of the rotary disk structures 200 by 90° under synchronous lifting and lowering coordination of the respective gas isolation structures 400 includes: sequentially moving the gas isolation structures 400 from top to bottom or from bottom to top, so that a rotating passage 404 of each of the gas isolation structures 400 is moved to a height at which one of the rotary disk structures 200 is located; and rotating the rotary disk structure 200 by 90°, after the rotating passage 404 of each of the gas isolation structures 400 is moved to the height at which one of the rotary disk structures 200 is located.

By coordinating the lifting and lowering of the gas isolation structure 400 with the rotation of the rotary disk structure 200, the gas isolation structure 400 can provide rotational space for the rotary disk structure 200 through its rotating passage 404 while maintaining the gas isolation effect. This allows each rotary disk structure 200 to rotate sequentially through the rotating passage 404 of the gas isolation structure 400, thereby achieving orderly switching of the wafer between different isolation spaces 101. This ensures the continuous execution of the atomic layer deposition process, enabling the entire film deposition process to proceed efficiently and stably, thus improving apparatus production efficiency.

Specifically, the coordination process between the gas isolation structure 400 and the rotary disk structure 200 is as follows: the gas isolation structure 400 moves sequentially from top to bottom or from bottom to top via the lifting mechanism until its rotating passage 404 reaches the height of a particular rotary disk structure 200. Once the gas isolation structure 400 is in place, the rotating structure 300 begins operation. The four protruding pins 302 on the side of the rotating shaft 301 engage with the four grooves 2011 on the rotary disk structure 200, causing the rotary disk structure 200 to rotate under the drive of the rotating structure 300.

The gas isolation structure 400 moves up and down under the action of the lifting mechanism, allowing rotary disk structures 200 at different heights to rotate sequentially through the rotating passage 404 of the gas isolation structure 400. Each time the rotating passage 404 reaches the height of the corresponding rotary disk structure 200, that rotary disk structure 200 rotates 90°.

In some embodiments, after each of the rotary disk structures 200 is further rotated by 90°, a second reaction gas is introduced into the fourth isolation space 101d and maintained continuously, while inert gas is continuously introduced into the second isolation space 101b and the third isolation space 101c.

By introducing a second reaction gas into the fourth isolation space 101d after the rotary disk structure 200 rotates a second 90°, while simultaneously continuously introducing inert gas into the second and third isolation spaces 101c, an alternating distribution pattern of reaction gas and purge gas is formed. Excess reaction gases on the wafer surface are removed by purging gas, allowing a layer of reaction gas A and reaction gas B adsorbed on the wafer surface to react and form an atomic-level film.

In some embodiments, the gas isolation structure 400 includes: a first gas curtain plate 401 with a first gas outlet at its bottom; and a second gas curtain plate 402 disposed at the bottom of the first gas curtain plate 401 and spaced apart from the first gas curtain plate 401 at a fixed distance, with a second gas inlet 402a at its top, the first gas outlet corresponding to the second gas inlet. During the preparation of the semiconductor film, the first gas outlet continuously ejects inert gas, and the second gas inlet absorbs inert gas, forming a gas curtain barrier between the first gas curtain plate 401 and the second gas curtain plate 402, achieving spatial isolation on both sides of the gas isolation structure 400.

The gas isolation structure 400 continuously ejects inert gas through the first gas outlet of the first gas curtain plate 401 and continuously draws in gas through the second gas inlet 402a of the second gas curtain plate 402, thereby forming a stable gas curtain barrier between the first gas curtain plate 401 and the second gas curtain plate 402. This effectively isolates the gases in different isolation spaces 101 within the reaction chamber 100, preventing the mixing and cross-contamination of different process gases. This allows for better control of the reaction environment during atomic layer deposition, improving the quality and uniformity of the film deposition.

The preparation method for a semiconductor film described in embodiments can be performed using the apparatus for film deposition described in the foregoing embodiments. For a detailed description of the apparatus for film deposition described in this embodiment, please refer to the corresponding descriptions in the foregoing embodiments; these descriptions will not be repeated here.

Although disclosed as above, the present disclosure is not limited to the foregoing description. A person skilled in the art can make various changes and modifications without departing from the spirit and the scope of the present disclosure. Thus, the scope of protection of the present disclosure should be subject to the scope defined by the claims.

1. An apparatus for film deposition, comprising:
a reaction chamber;
a plurality of rotary disk structures spaced apart from each other in a height direction, each of the rotary disk structures including a fitting member and a plurality of wafer slots distributed circumferentially along the fitting member;
a rotating structure extending in the height direction and movable along the height direction, the rotating structure being disposed in the fitting member of a single rotary disk structure and configured to drive the rotary disk structure to rotate;
a plurality of gas isolation structures extending in the height direction, the plurality of gas isolation structures partitioning the reaction chamber into a plurality of isolation spaces, each of the gas isolation structures being provided with a rotating passage through which one rotary disk structure is rotatably passable; wherein a number of isolation spaces is equal to a number of wafer slots in the rotary disk structure;
a gas inlet unit, disposed in the reaction chamber; and
a gas exhaust unit, disposed in the reaction chamber.

2. The apparatus for film deposition according to claim 1, wherein the rotating structure
comprises: a rotating shaft extending in the height direction; and
a plurality of protruding pins radially distributed on a sidewall of the rotating shaft at a same height;
wherein the fitting member is disposed at a center of the plurality of wafer slots in the rotary disk structure, and the fitting member comprises a groove for the protruding pin to be inserted, enabling the rotating shaft to drive the rotary disk structure to rotate.

3. The apparatus for film deposition according to claim 2, wherein the plurality of protruding pins are arranged in a ring array at equal angles with the rotating shaft as a center point; and
wherein a plurality of grooves in the fitting member are interconnected and configured to receive the plurality of protruding pins on the rotating shaft.

4. The apparatus for film deposition according to claim 1, wherein the rotary disk structure comprises:
a support arm, configured to support the wafer slot, wherein one end of the support arm is connected to a sidewall of the fitting member, and the other end of the support arm is connected to the wafer slot.

5. The apparatus for film deposition according to claim 1, wherein the gas isolation structure comprises:
a first gas curtain plate; and
a second gas curtain plate disposed at a bottom of the first gas curtain plate and spaced apart from the first gas curtain plate at a fixed distance, a space between the second gas curtain plate and the first gas curtain plate defining the rotating passage.

6. The apparatus for film deposition according to claim 5, wherein the gas isolation structure further comprises:
a gas curtain plate fixing member, configured to maintain a fixed distance between the first gas curtain plate and the second gas curtain plate, wherein the gas curtain plate fixing member is disposed between the bottom of the first gas curtain plate and the top of the second gas curtain plate, and is located at an outer edge of the first gas curtain plate and the second gas curtain plate away from the rotating structure.

7. The apparatus for film deposition according to claim 5, wherein a top of the first gas curtain plate is provided with a first gas inlet, and the bottom of the first gas curtain plate comprises a plurality of first gas outlets arranged at intervals, the plurality of first gas outlets being in fluid communication with the first gas inlet, such that an inert gas is delivered to a top of the second gas curtain plate through the first gas inlet and the first gas outlets;
wherein the top of the second gas curtain plate is provided with a plurality of second gas inlets corresponding to the first gas outlets arranged at intervals for absorbing gas, and a bottom of the second gas curtain plate is provided with second gas outlets;
wherein the gas inlet unit comprises: a gas curtain gas inlet assembly, configured to provide isolation gas to the gas isolation structure, wherein the gas curtain gas inlet assembly is in fluid communication with the first gas inlet;
wherein the gas exhaust unit comprises: a gas curtain exhaust assembly, configured to extract gas from the gas isolation structure, wherein the gas curtain exhaust assembly is in fluid communication with the second gas outlet corresponding to the second gas inlet.

8. The apparatus for film deposition according to claim 1, wherein the gas isolation structure extends through a top and a bottom of the reaction chamber in the height direction, and the gas isolation structure is slidable in the height direction to move upward and downward.

9. The apparatus for film deposition according to claim 8, wherein the apparatus for film deposition further comprises: a lifting mechanism, disposed below the reaction chamber, wherein an output end of the lifting mechanism is connected to a bottom of the gas isolation structure.

10. The apparatus for film deposition according to claim 1, wherein the gas inlet unit further comprises a plurality of process gas inlet assemblies, the gas exhaust unit further comprises a plurality of waste gas exhaust assemblies, and one of the isolation spaces contains one process gas inlet assembly and one waste gas exhaust assembly;
wherein the process gas inlet assembly is disposed on a side of the wafer slot near the rotating structure, and the waste gas exhaust assembly is disposed on a side of the wafer slot away from the rotating structure; or
wherein the waste gas exhaust assembly is disposed on the side of the wafer slot near the rotating structure, and the process gas inlet assembly is disposed on the side of the wafer slot away from the rotating structure.

11. The apparatus for film deposition according to claim 10, wherein the process gas inlet assembly extends in the height direction, each of the process gas inlet assemblies is provided with a jet pipe corresponding one-to-one with a plurality of wafer slots along the height direction, and the jet pipe is disposed above a side of the corresponding wafer slot.

12. The apparatus for film deposition according to claim 10, wherein the plurality of process gas inlet assemblies are arranged in a ring array at equal angles with the rotating structure as a center point.

13. The apparatus for film deposition according to claim 12, wherein the plurality of the waste gas exhaust assemblies are arranged in a ring array at equal angles with the rotating structure as a center point, and a line connecting the center point of the process gas inlet assemblies and the center point of the waste gas exhaust assemblies passes through a center point of the rotating structure.

14. The apparatus for film deposition according to claim 1, wherein the wafer slots in the rotary disk structure are arranged in a ring array at equal angles with the rotating structure as a center point.

15. The apparatus for film deposition according to claim 1, wherein each of the rotary disk structures comprises four wafer slots.

16. A preparation method for a semiconductor film, employing an apparatus for film deposition according to claim 1, wherein each of rotary disk structures comprises four wafer slots, and a reaction chamber is partitioned into four isolation spaces by gas isolation structures, wherein a first isolation space and a fourth isolation space are diagonally arranged, and a second isolation space and a third isolation space are diagonally arranged, the preparation method for the semiconductor film comprising:
transferring wafers into the wafer slots of a plurality of layers of the rotary disk structures in the reaction chamber;
introducing an inert gas into the reaction chamber to perform purging, after transferring the wafers into the wafer slots;
introducing a first reaction gas into the first isolation space while continuously supplying the first reaction gas thereto, and introducing an inert gas into the second isolation space, the third isolation space, and the fourth isolation space;
rotating each of the rotary disk structures by 90° under synchronous lifting and lowering coordination of the respective gas isolation structures;
introducing a second reaction gas into the fourth isolation space while continuously supplying the second reaction gas thereto, and continuously introducing the inert gas into the second isolation space and the third isolation space, after each of the rotary disk structures is further rotated by 90°;
thereafter, under synchronous lifting and lowering coordination of the respective gas isolation structures, rotating each of the rotary disk structures by 90° and maintaining the rotary disk structures for a preset period of time after each rotation; wherein a wafer in each wafer slot sequentially passes through the first isolation space, the third isolation space, the fourth isolation space, and the second isolation space to complete one atomic layer film deposition process, and under synchronous lifting and lowering coordination of the respective gas isolation structures, each wafer repeatedly passes through the first isolation space, the third isolation space, the fourth isolation space, and the second isolation space, achieving multiple cyclic depositions on the wafer to a predetermined thickness, thereby completing the preparation of the film on the wafer.

17. The preparation method according to claim 16, wherein the preparation method further includes: performing a vacuum treatment on the reaction chamber, after transferring the wafers into the wafer slots of the plurality of layers of the rotary disk structures in the reaction chamber.

18. The preparation method according to claim 16, wherein each of the gas isolation structure comprises: a first gas curtain plate; a second gas curtain plate disposed at a bottom of the first gas curtain plate and spaced apart from the first gas curtain plate at a fixed distance, a top of the second gas curtain plate being provided with a plurality of second gas inlets, wherein the second gas inlets correspond to the first gas outlets;
wherein during the preparation of the semiconductor film, the first gas outlet continuously ejects inert gas, and the second gas inlet absorbs inert gas, forming a gas curtain barrier between the first gas curtain plate and the second gas curtain plate, achieving spatial isolation on both sides of the gas isolation structure.

19. The preparation method according to claim 16, wherein the process of rotating each of the rotary disk structures by 90° under synchronous lifting and lowering coordination of the respective gas isolation structures includes:
sequentially moving the gas isolation structures from top to bottom or from bottom to top, so that a rotating passage of each of the gas isolation structures is moved to a height at which one of the rotary disk structures is located; and
rotating the rotary disk structure by 90°, after the rotating passage of each of the gas isolation structures is moved to the height at which one of the rotary disk structures is located.
